(19) United States
(12) Patent Application Publication
(10) Pub. No.: US 2016/0259245 A1
(43) Pub. Date: Sep. 8, 2016

(54) REAGENT FOR ENHANCING GENERATION OF CHEMICAL SPECIES AND MANUFACTURING APPARATUS

(71) Applicant: TOYO GOSEI CO., LTD., Ichikawa-shi, Chiba (JP)

(72) Inventors: Satoshi Enomoto, Ichikawa-shi, Chiba (JP); Takashi Miyazawa, Inzai-shi, Chiba (JP)

(21) Appl. No.: 15/027,855

(22) PCT Filed: Oct. 6, 2014
(86) PCT No.: PCT/JP2014/005089

§ 371 Date: Apr. 7, 2016

Related U.S. Application Data
(60) Provisional application No. 61/961,187, filed on Oct. 7, 2013.

(51) Int. Cl. G03F 7/038; G03F 7/20

(52) U.S. Cl. CPC G03F 7/0382; G03F 7/2022

(57) ABSTRACT

A reagent that enhances acid generation of a photoacid generator and composition containing such reagent is disclosed.

### CROSS-REFERENCE TO RELATED APPLICATIONS

This application is a national phase entry under 35 U.S.C. §371 of International Patent Application PCT/JP2014/005089, filed Oct. 6, 2014, designating the United States of America and published in English as International Patent Publication WO 2015/052914 A1 on April 16, 2015, which claims the benefit under 35 U.S.C. section 119(e) and Article 8 of the Patent Cooperation Treaty to U.S. Provisional Patent Application Ser. No. 61/961,187, filed on Oct. 7, 2013, the disclosure of which is hereby incorporated herein in its entirety by this reference.

### TECHNICAL FIELD

An aspect of the application relates to the fields of chemistry and a reagent that can produce at least one of an intermediate and a photosensitizer that is capable of enhancing a generation of a chemical species, such as acid and base from a precursor. Such intermediate or photosensitizer can transfer its energy or electron to the precursor or receive the precursor's energy or electron to generate the chemical species. A manufacturing apparatus also relates to an aspect of this disclosure. The generation of the chemical species is able to be highly intensified by using such manufacturing apparatus.

### BACKGROUND

Current high-resolution lithographic processes are based on chemically amplified resists (CARs) and are used to pattern features with dimensions less than 100 nm.

A method for forming pattern features with dimensions less than 100 nm is disclosed in U.S. Patent 7,851,252 (filed on February 17, 2009), the contents of the entirety of which are incorporated herein by this reference.

### BRIEF SUMMARY

A reagent relating to an aspect of this disclosure is characterized by that: (i) the reagent is capable of being a constituent of a composition containing a precursor; (ii) the reagent is capable of generating a first chemical species in at least one of the composition, a solution containing the composition, and a film formed from the composition; and (iii) the precursor is capable of generating a second chemical species through an interaction with the first chemical species.

With regard to such reagent, it is preferred that the first chemical species is capable of being generated from the reagent by a first exposure of at least one of the composition, the solution and the film to at least one of a first electromagnetic ray, the wavelength of which is a first wavelength and a first particle ray.

With regard to such reagent, it is preferred that the precursor is capable of generating a second chemical species by a second exposure of at least one of the composition, the solution or the film to at least one of a second electromagnetic ray, the wavelength of which is a second wavelength and a second particle ray.

With regard to such reagent, it is preferred that the second exposure of at least one of the composition, the solution or the film is carried out using a pulsed light as the second electromagnetic ray.

With regard to such reagent, it is preferred that a first period in which the first exposure is carried out overlaps temporally a second period in which the second exposure is carried out.

With regard to such reagent, it is preferred that a first period in which the first exposure is carried out does not overlap temporally a second period in which the second exposure is carried out.

With regard to such reagent, it is preferred that the first chemical species has a lifetime in at least one of the composition, the solution and the film and the second exposure is carried out within the lifetime of the first chemical species.

With regard to such reagent, it is preferred that the precursor is capable of receiving an electron from the first chemical species by an excitation of the first chemical species by the second exposure.

With regard to such reagent, it is preferred that the first chemical species is capable of generating a first product.

With regard to such reagent, it is preferred that the first chemical species is capable of generating a first product through an interaction with the precursor.

With regard to such reagent, it is preferred that the first product is capable of acting as a photosensitizer in at least one of the composition, the solution and the film.

With regard to such reagent, it is preferred that the first product is capable of enhancing a generation of the second chemical species by acting as the photosensitizer.

With regard to such reagent, it is preferred that the first exposure is carried out using the first electromagnetic ray while the second exposure is carried out using the second electromagnetic ray. It is preferred that the second wavelength is longer than the first wavelength.

With regard to such reagent, it is preferred that the generation of the second chemical species is enhanced through a third exposure of the at least one of the composition, the solution and the film to at least one of a third electromagnetic ray, the wavelength of which is a third wavelength and a third particle ray.

With regard to such reagent, it is preferred that the first exposure is carried out by the first electromagnetic ray while the third exposure is carried out by the third electromagnetic ray. It is preferred that the third wavelength is longer than the first wavelength.

With regard to such reagent, it is preferred that the third exposure is carried out using the third electromagnetic ray, and the third wavelength is longer than 250 nm. It is more preferable that the third wavelength is longer than 300 nm.

With regard to such reagent, it is preferred that the first exposure yields a third chemical species in the at least one of the composition, the solution and the film and the first chemical species is generated from the reagent through a reaction of the reagent with the third chemical species.

With regard to such reagent, it is preferred that the first chemical species is capable of being generated from the reagent by having a hydrogen atom of the reagent abstracted by the third chemical species.

A composition relating to an aspect of this disclosure includes such reagent mentioned above.

A composition relating to an aspect of this disclosure includes: (i) a first reagent that is capable of generating a first chemical species in at least one of the composition, a solution containing the composition, and a film formed from the composition; and (ii) a precursor that is capable of generating a second chemical species through interaction with the first chemical species.

With regard to such composition, it is preferred that the first reagent is capable of generating the first chemical species through a first exposure of at least one of the composition, the solution, and the film to at least one of a first electromagnetic ray, the wavelength of which is a first wavelength and a first particle ray.

With regard to such composition, it is preferred that the precursor is capable of generating the second chemical species through a second exposure of at least one of the composition, the solution, and the film to at least one of a second electromagnetic ray, the wavelength of which is a second wavelength and a second particle ray.

With regard to such composition, it is preferred that the first chemical species is capable of generating a first product and the first product is capable of acting as a photosensitizer.

With regard to such composition, it is preferred that the first chemical species is capable of generating a first product and the precursor is capable of generating the second chemical species through a third exposure of at least one of the composition, the solution, and the film by at least one of a third electromagnetic ray, the wavelength of which is a third wavelength and a third particle ray.

With regard to such composition, it is preferred that the first electromagnetic ray and the first particle ray are an extreme ultraviolet light (EUV) and an electron beam (EB), respectively.

With regard to such composition, it is preferred that the third exposure is carried out using the third wavelength, which is longer than 250 nm.

With regard to such composition, it is preferred that the second wavelength is longer than the third wavelength.

A manufacturing apparatus relating to an aspect of this disclosure includes a first ray source that is able to output at least one of a first electromagnetic ray and a first particle ray, a second ray source that is able to output at least one of a second electromagnetic ray and second particle ray, and a first member on which an object is to be processed is disposed.

With regard to such manufacturing apparatus, it is preferred that the first ray source, the second ray source, and the first member are configured such that at least a part of a first period in which a first exposure of the object by the at least one of the first electromagnetic ray and the first particle ray is carried out overlaps temporally at least a part of a second period in which a second exposure of the object by the at least one of the second electromagnetic ray and the second particle ray is carried out.

With regard to such manufacturing apparatus, it is preferred that the first ray source, the second ray source, and the first member are configured such that a first period in which a first exposure of the object by the at least one of the first electromagnetic ray and the first particle ray is carried out does not overlap temporally a second period in which a second exposure of the object by the at least one of the second electromagnetic ray and the second particle ray is carried out.

With regard to such manufacturing apparatus, it is preferred that the second ray source is capable of outputting the at least one of the second electromagnetic ray and the second particle ray with a delay of a predetermined amount of time from the output of the at least one of the first electromagnetic ray and the first particle ray from the first ray source.

With regard to such manufacturing apparatus, it is preferred that such manufacturing apparatus further includes a third ray source that is capable of outputting at least one of a third electromagnetic ray and a third particle ray.

With regard to such manufacturing apparatus, it is preferred that the second ray source that is able to output at least one of a third electromagnetic ray and a third particle ray in addition to the at least one of the second electromagnetic ray and the second particle ray.

With regard to such manufacturing apparatus, it is preferred that the second wavelength is longer than the third wavelength.

With regard to such manufacturing apparatus, it is preferred that the first ray source, the second ray source, and the first member are configured such that a first area of a first portion of the object exposed to the at least one of the first electromagnetic ray and the first particle ray is carried out is smaller than a second area of a second portion of the object exposed to the at least one of the second electromagnetic ray and the second particle ray.

With regard to such manufacturing apparatus, it is preferred that the first ray source, the second ray source, and the first member are configured such that the first portion is included in the second portion; and the second portion is exposed to the at least one of the second electromagnetic ray and the second particle ray after the first portion is exposed to the at least one of the first electromagnetic ray and the first particle ray.

With regard to such manufacturing apparatus, it is preferred that the first electromagnetic ray and the first particle ray are an EUV and an EB.

With regard to such manufacturing apparatus, it is preferred that the second ray source is an Nd:YAG laser.

With regard to such manufacturing apparatus, it is preferred that the second ray source is an Nd:YAG laser and the second electromagnetic ray and the third electromagnetic ray are the second harmonic of the Nd:YAG laser and the third harmonic of the Nd:YAG laser, respectively.

A method of manufacturing a device relating to an aspect of this disclosure is characterized by using such manufacturing apparatus mentioned above.

A method of manufacturing a device relating to an aspect of this disclosure includes: (i) placing such composition mentioned above on a member, such that a film containing the composition is disposed on the member; and (ii) first exposing the film to at least one of an electron beam and a first light, the wavelength of which is a first wavelength. With regard to such method, it is preferred that the first wavelength is shorter than 50 nm.

With regard to such method, it is preferred that such method further includes a second exposing the film to a second light, the wavelength of which is a second wavelength. It is preferred that the first wavelength is different from the second wavelength.

With regard to such method, it is preferred that a first period in which the first exposing is carried out does not overlap temporally a second period in which the second exposing is carried out.

With regard to such method, it is preferred that the first chemical species is generated through the first exposing.

With regard to such method, it is preferred that a first product is generated from the first chemical species in the film.

With regard to such method, it is preferred that such method further includes a third exposing the film to at least one of a third electromagnetic ray and a third particle ray.

With regard to such method, it is preferred that the precursor generates the second chemical species through the third exposing.

With regard to such method, it is preferred that the first product enhances the generation of the second chemical species from the precursor by absorbing the third electromagnetic ray.

A method of manufacturing a device relating to an aspect of this disclosure includes: (i) placing a composition containing a reagent on a member such that a film containing the composition is disposed on the member; (ii) generating a first chemical species from the reagent, the first chemical species having a lifetime in the film; and (iii) exciting the first chemical species within the lifetime of the first chemical species.

With regard to such method, it is preferred that the first chemical species is generated by a first exposure of the film to at least one of a first electromagnetic ray and a first particle ray; and the exciting of the first chemical species is carried out by a second exposure of the film to at least one of a second electromagnetic ray and the second particle ray.

A reagent that is able to produce an intermediate enhancing generation of a chemical species such as acid and a composition are disclosed in this disclosure. Typically, such intermediate assists the generation of Bronsted acid or base from a precursor. Furthermore, such intermediate can be applied to the generation of Lewis acid and base. Typically, such intermediate is formed by an irradiation of the reagent with an electromagnetic ray or a particle ray. More typically, an EUV or an EB are used for such electromagnetic ray or particle ray, respectively. An excitation of such intermediate during its lifetime can make electron transfer from the intermediate to the precursor facile, even if the precursor does not have enough electron-accepting ability or the intermediate does not have enough electron-donating ability. Alternatively, an excitation of such intermediate during its lifetime can make electron transfer from the precursor to the intermediate facile, even if the precursor does not have enough electron-donating ability or the intermediate does not have enough electron-accepting ability. The precursor generates such chemical species through the electron transfer involved with the intermediate.

Such reagent may have a protecting group for the carbonyl group of a ketone compound or the hydroxy group of alcohol compound. Typically, such ketone compound or alcohol compound is generated by deprotection reaction of the reagent by acid generated from a photoacid generator (PAG). The generated ketone compound or alcohol compound generates an intermediate such as ketyl radical. The excitation of such intermediate makes transferring its electron to the PAG facile, even if the PAG does not have enough electron-accepting ability or the intermediate does not have enough electron-donating ability. The PAG generates acid by receiving the electron from the excited intermediate.

A product formed by excitation of an intermediate such as ketyl radical can also enhance a generation of the chemical species from the precursor as a photosensitizer. More concretely, an excitation of the ketyl radical results in a corresponding ketone compound, which can act as a photosensitizer for the generation of acid from the PAG.

A composition containing such reagent that is to form such intermediate, a precursor that is to form a chemical species, and a compound that is to react with the chemical species can be applied as photoresist to manufacturing of electronic devices such as a semiconductor device and an electro-optical device.

For example, after a coating film of the composition is exposed to an excimer laser, an EUV light or an EB in a first step, an irradiation of the coating film is carried out in a second step during a lifetime of the intermediate generated in the first step. In the second step, the coating film can be exposed to a light, the wavelength of which is longer than that of the EUV light, a UV light, the wavelength of which is longer than 200 nm or a visible light.

A product generated through the excitation of the intermediate in the second step is able to act as a photosensitizer for enhancing the generation of the chemical species from the precursor. In other words, an excitation of such product is able to enhance the generation of the chemical species.

The composition containing such reagent mentioned above, a PAG, and a resin containing a protective group such as ester, and an ether group that is able to decompose by reacting with acid generated from the PAG can be used as a chemically amplified resist (CAR).

It is preferred that, to attain the high resolution lithographic property, an unexposure area in the first step is inactive to the light or the particle ray with which the intermediate or the photosensitizer is irradiated in the second step.

### BRIEF DESCRIPTION OF THE DRAWINGS

In the drawings, which illustrate what is currently considered to be the best mode for carrying out the disclosure:

FIG. 1 shows a manufacturing apparatus equipped with an EUV light source and a laser light source related to an aspect of this disclosure.

FIG. 2 shows a manufacturing apparatus equipped with an EUV light source and a laser light source related to another aspect of this disclosure.

FIG. 3 shows a manufacturing apparatus equipped with an EB source and a laser light source related to an aspect of this disclosure.

FIG. 4 shows a typical reaction scheme of a composition containing a reagent related to an aspect of this disclosure.

FIG. 5 shows a typical reaction scheme of a composition containing a reagent relating to another aspect of this disclosure.

FIG. 6 shows fabrication processes of a device such as integrated circuit (IC) using a CAR containing a reagent relating to an aspect of this disclosure.

### DETAILED DESCRIPTION

Experimental Procedures

### Synthesis of 2-[1-(4-methoxy-phenyl)-ethoxy]-tetrahydropyran (Reagent 1)

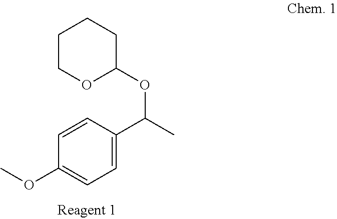 [SMILES: COc1ccc(C(C)OC2CCCCO2)cc1]

2.75 g of 2H-dihydropyran and 0.74 g of pyridinium p-toluenesulfonate are dissolved in 30.0 g of methylene chloride. 2.0 g of 1-(4-methoxyphenyl)-ethanol dissolved by 8.0 g of methylene chloride is added dropwise to the mixture containing 2H-dihydropyran and pyridinium p-toluenesulfonate over 30 minutes. After that, the mixture is stirred at 25 degrees Celsius for 3 hours. Afterward, the mixture is further stirred after addition of 3% aqueous solution of sodium carbonate and then extracted with 20.0 g of ethyl acetate. The organic phase is washed with water. Thereafter, ethyl acetate is distilled away, thereby obtaining 1.99 g of 2-[1-(4-methoxy-phenyl)-ethoxy]-tetrahydropyran (Reagent 1).

### Synthesis of 2-[bis-(4-methoxy-phenyl)-methoxy]etrahydro-pyran (Reagent 2)

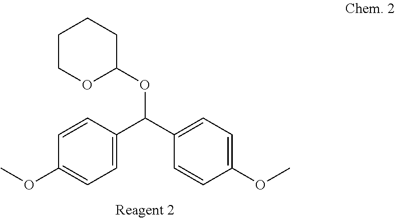

2.75 g of 2H-dihydropyran and 0.74 g of pyridinium p-toluenesulfonate are dissolved in 30.0 g of methylene chloride. 2.0 g of bis-(4-methoxyphenyl)-methanol dissolved by 8.0 g of methylene chloride is added dropwise to the mixture containing 2H-dihydropyran and pyridinium p-toluenesulfonate over 30 minutes. After that, the mixture is stirred at 25 degrees Celsius for 3 hours. Thereafter, the mixture is further stirred after addition of 3% aqueous solution of sodium carbonate, then extracted with 20.0 g of ethyl acetate and the organic phase is washed with water. Thereafter, ethyl acetate is distilled away, thereby obtaining 1.99 g of 2-[bis-(4-methoxy-phenyl)-methoxy]-tetrahydro-pyran (Reagent 2).

### Synthesis of bis-(4-methoxy-phenyl)-dimethoxymethane (Reagent 3)

2.0 g of 4,4′-dimethoxy-benzophenone, 0.05 grams of bismuth (III) trifluoromethanesulfonate and 5.7 g of trimethyl orthofomate are dissolved in 5.0 g of methanol. The mixture is stirred at reflux temperature for 42 hours. Afterward, the mixture is cooled at 25 degrees Celsius and further stirred after addition of 5% aqueous NaHCO₃ solution. Next, the mixture is extracted with 30 g ethyl acetate and the organic phase is washed with water. Thereafter, ethyl acetate is distilled away, and the resultant is purified by silica gel column chromatography (ethyl acetate:hexane=1:9), thereby obtaining 1.71 g of bis-(4-methoxy-phenyl)-dimethoxymethane (Reagent 3).

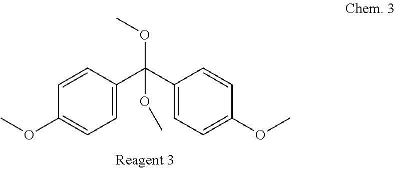

### Synthesis of 2,4-dimethoxy-4′-(2-vinyloxy-ethoxy)-benzophenone

2.00 g of 2,4-dimethoxy-4′-hydroxybenzophenone, 2.48 g of 2-chloroethyl vinyl ether and 3.21 g of potassium carbonate are dissolved in 12.0 g of dimethyl formamide. The mixture is stirred at 110 degrees Celsius for 15 hours. Next, the mixture is cooled to 25 degrees Celsius and further stirred after addition of 60.0 g of water, then extracted with 24.0 g of toluene and the organic phase is washed with water. Thereafter, toluene is distilled away, thereby obtaining 3.59 g of 2,4-dimethoxy-4′-(2-vinyloxy)-ethoxy-benzophenone.

### Synthesis of 2,4-dimethoxy-4′-(2-hydroxy-ethoxy)-benzophenone

3.59 g of 2,4-dimethoxy-4′-(2-vinyloxy-ethoxy)-benzophenone, 0.28 g of pyridinium p-toluenesulfonate and 2.1 g of water are dissolved in 18.0 g of acetone. The mixture is stirred at 35 degrees Celsius for 12 hours. Thereafter, the mixture is further stirred after addition of 3% aqueous solution of sodium carbonate, then extracted with 28.0 g of ethyl acetate and the organic phase is washed with water. Thereafter, ethyl acetate is distilled away, thereby obtaining 3.04 g of 2,4-dimethoxy-4′-(2-hydroxy-ethoxy-benzophenone).

### Synthesis of (2,4-dimethoxyphenyl)-[4′-(2-methacryloxy-ethyl)-phenyl]-benzophenone

3.0 g of 2,4-dimethoxy-4′-(2-hydroxy-ethoxy)-benzophenone and 1.7 g of methacrylic anhydride are dissolved in 21 g of tetrahydrofuran. 1.2 g of triethylamine dissolved in 3.6 g of tetrahydrofuran is added dropwise to the tetrahydrofuran solution containing 2,4-dimethoxy-4′-(2-hydroxy-ethoxy)-benzophenone over 10 minutes. Thereafter, the mixture is stirred at 25 degrees Celsius for 3 hours. Next, the mixture is further stirred after addition of water, then extracted with 30 g of ethyl acetate and the organic phase is washed with water. Thereafter, ethyl acetate is distilled away, and the residue is purified by silica gel column chromatography (ethyl acetate:hexane=1:9), thereby obtaining 2.72 g of (2,4-dimethoxyphenyl)-[4′-(2-methacryloxy-ethyl)-phenyl]-benzophenone.

### Synthesis of (2,4-dimethoxyphenyl)-[4′-(2-methacryloxy-ethoxy)-phenyl]-methanol

2.7 g of (2,4-dimethoxyphenyl)-[4′-(2-methacryloxy-ethyl)-phenyl]-benzophenone is dissolved in 21.6 g of tetrahydrofuran. 0.55 g of sodium boron hydride dissolved in water is added to the tetrahydrofuran solution. The mixture is stirred at 25 degrees Celsius for 2 hours. Next, the mixture is added to the 120 g of water, then extracted with 20.0 g of ethyl acetate and the organic phase is washed with water. Thereafter, ethyl acetate is distilled away, thereby obtaining 2.4 g of (2,4-dimethoxyphenyl)44′-(2-methacryloxy-ethoxy)-phenyl]-methanol.

### Synthesis of 2-methyl-acrylic acid 2-{4-[(2,4-dimethoxy-phenyl)-(1-ethoxy-ethoxy)-methyl]-phenoxyl-ethyl ester

1.4 g of ethyl vinyl ether and 0.06 g of pyridinium p-toluenesulfonate are dissolved in 18.0 g of methylene chloride. 1.5 g of (2,4-dimethoxyphenyl)-[4′-(2-methacryloxy-ethyl)-phenyl)-methanol dissolved by 8.0 g of methylene chloride is added dropwise to the methylene chloride solution containing ethyl vinyl ether and pyridinium p-toluenesulfonate over 30 minutes. Thereafter, the mixture is stirred at 25 degrees Celsius for 3 hours. Next, the mixture is further stirred after addition of 3% aqueous solution of sodium carbonate, then the organic phase is washed with water. Thereafter, methylene chloride is distilled away, and the resultant is purified by silica gel column chromatography (ethyl acetate:hexane=5:95), thereby obtaining 1.31 g of 2-methyl-acrylic acid 2-{4-[(2,4-dimethoxy-phenyl)-(1-ethoxy-ethoxy)-methyl]-phenoxy -ethyl ester.

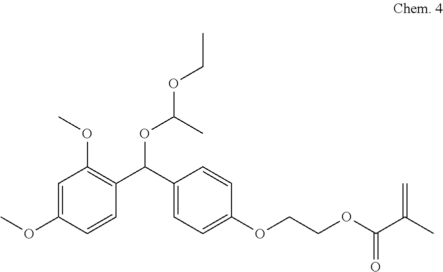 [SMILES: C=C(C)C(=O)OCCOc1ccc(C(OC(C)OCC)c2ccc(OC)cc2OC)cc1]

A solution containing 5.0 g of alpha-methacryloyloxy-gamma-butylolactone, 6.03 g of 2-methyladamantane-2-methacrylate, and 4.34 g of 3-hydroxyadamantane-1-methacrylate, 0.51 g of dimethyl-2,2′-azobis(2-methylpropionate), and 26.1 g of tetrahydrofuran is prepared. The prepared solution is added dropwise over 4 hours to 20.0 g of tetrahydrofuran placed in a flask while stirring and boiling. After the addition of the prepared solution, the mixture is heated to reflux for 2 hours and cooled to room temperature. Addition of the mixture by drops to a mixed liquid containing 160 g of hexane and 18 g of tetrahydrofuran while vigorously stirring precipitates the copolymer. The copolymer is isolated by filtration. Purification of the copolymer is carried out by vacuum drying following two washings by 70 g of hexane, thereby obtaining 8.5 g of white powder of the copolymer (Resin A).

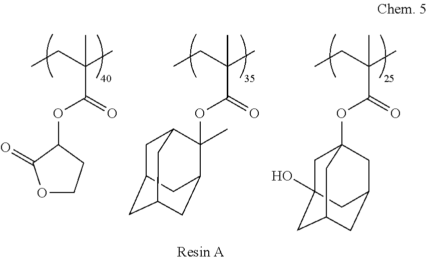

A solution containing 0.98 g of 2-methyl-acrylic acid 2-{4-[(2,4-dimethoxy-phenyl)-(1-ethoxy-ethoxy)-methyl]-phenoxy}-ethyl ester, 3.0 g of alpha-methacryloyloxy-gamma-butylolactone, 2.6 g of 2-methyladamantane-2-methacrylate, 3.1 g of 3-hydroxyadamantane-1-methacrylate, 0.20 g of butyl mercaptane, 0.51 g of dimethyl-2,2′-azobis(2-methylpropionate) and 11.2 g of tetrahydrofuran is prepared. The prepared solution is added dropwise over 4 hours to 8.0 g of tetrahydrofuran placed in a flask while stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran while vigorously stirring precipitates the copolymer. The copolymer is isolated by filtration. Purification of the copolymer is carried out by vacuum drying following two washings by 40 g of hexane, thereby obtaining 7.1 g of white powder of the copolymer (Resin B). The diarylmethanol moiety B-1 functioning as an AGE in Resin B is protected by a protecting group.

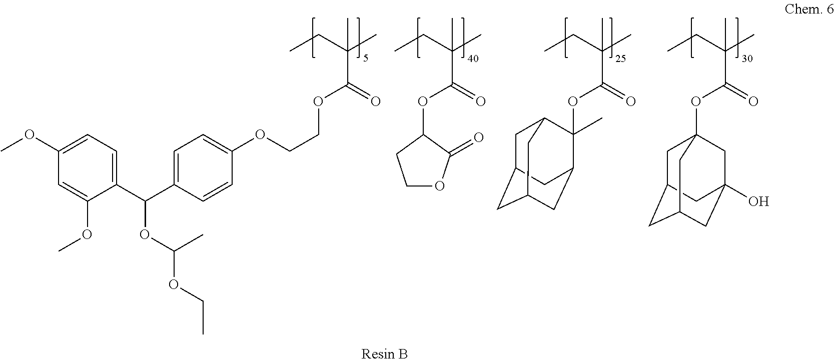

A solution containing 3.0 g of alpha-methacryloyloxy-gamma-butylolactone, 2.6 g of 2-methyladamantane-2-methacrylate, 3.1 g of 3-hydroxyadamantane-1-methacrylate, 1.1 g of 5-phenyl-dibenzothiophenium 1,1-difluoro-2-(2-methyl-acryloyloxy)-ethanesulfonate, 0.20 g of butyl mercaptane, 0.51 g of dimethyl-2,2′-azobis(2-methylpropionate) and 12.2 g of tetrahydrofuran is prepared. 5-phenyl-dibenzothiophenium 1,1-difluoro-2-(2-methyl-acryloyloxy)-ethanesulfonate functions as a PAG moiety. The prepared solution is added dropwise over 4 hours to 8.0 g of tetrahydrofuran placed in a flask while stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran while vigorously stirring precipitates the copolymer. The copolymer is isolated by filtration. Purification of the copolymer is carried out by vacuum drying following two washings by 40 g of hexane and two washings by methanol, thereby obtaining 5.7 g of white powder of the copolymer (Resin C).

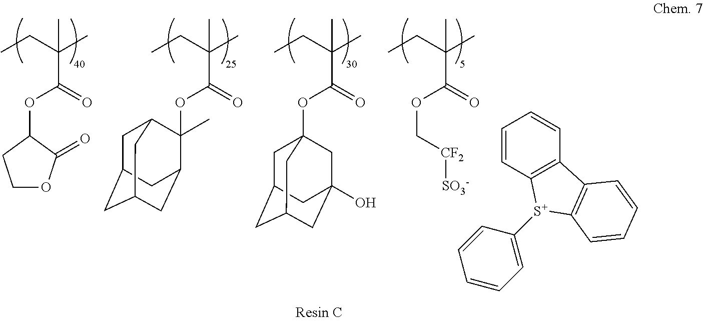

Preparation of samples for evaluation (the “Evaluation Samples”)

Constituents of each of Evaluation Samples 1-11 are shown in Table 1. Each of all the Evaluation Samples contains 8000 mg of cyclohexanone. Each of Evaluation Samples 1-3 contains 24.1 mg of triphenylsulfonium nonafluorobutanesulfonate (TPS-PFBS) as PAG. Each of Evaluation Samples 4-6 contains 24.9 mg of diphenyliodonium nonafluorobutanesulfonate (DPI-PFBS) as a PAG. Each of Evaluation Samples 7-10 contains 24.1 mg of 5-phenyl-dibenzothiophenium nonafluorobutanesulfonate (PBpS-PFBS) as a PAG. Each of Evaluation Samples 1-9 contains 600 mg of Resin A. Evaluation Samples 10 and 11 contain Resins B and C, respectively. Each of Evaluation Samples 2, 3, 4, 6, 7 and 9 contains 0.025 mmol of Reagent 1, while each of Evaluation Samples 5, 8 and 11 contains 0.025 mmol of Reagent 2. Each of Evaluation Samples 3, 6 and 9 contains 0.012 mmol of Reagent 1 and 0.013 mmol of Reagent 3.

TABLE 1
Evaluation Samples for evaluation for efficiencies of patterning

| | Resin | PAG | Additive 1 | Additive 2 | Solvent |
|---|---|---|---|---|---|
| Evaluation | Resin A | TPS-PFBS | — | — | Cyclo- |
| Sample 1 | | | | | hexanone |
| Evaluation | | | Reagent 1 | — | |
| Sample 2 | | | | | |
| Evaluation | | | Reagent 1 | Reagent 3 | |
| Sample 3 | | | | | |
| Evaluation | | DPI-PFBS | Reagent 1 | — | |
| Sample 4 | | | | | |
| Evaluation | | | Reagent 2 | — | |
| Sample 5 | | | | | |
| Evaluation | | | Reagent 1 | Reagent 3 | |
| Sample 6 | | | | | |
| Evaluation | | PBpS-PFBS | Reagent 1 | — | |
| Sample 7 | | | | | |
| Evaluation | | | Reagent 2 | — | |
| Sample 8 | | | | | |
| Evaluation | | | Reagent 1 | Reagent 3 | |
| Sample 9 | | | | | |
| Evaluation | Resin B | PBpS-PFBS | — | — | |
| Sample 10 | | | | | |
| Evaluation | Resin C | — | Reagent 2 | — | |
| Sample 11 | | | | | |

Evaluation of Sensitivity

Before applying an Evaluation Sample to an Si wafer, hexamethyldisilazane (HMDS, Tokyo Chemical Industry) is spin-coated at 2000 rpm for 20 seconds on the surface of the Si wafer and baked at 110 degrees Celsius for 1 minute. Then, the Evaluation Sample is spin-coated on the surface of the Si wafer that has been treated with HMDS at 4000 rpm for 20 seconds to form a coating film of the Evaluation Sample. The prebake of the coating film is performed at 110 degrees Celsius for 60 seconds. Then, the coating film is exposed to 100 keV EB output from the EB radiation source through the 2-micrometer line and space-patterned mask. After the EB exposure, the coating film is exposed to a white LED light with a delay of 0.5-1.0 microseconds from the EB exposure to excite a radical generated from Reagent 1, Reagent 2, B-1 moiety of Resin B through the EB exposure during lifetimes of the radical. Since then, an irradiation of the coating film with a UV light, the wavelength of which is carried out at an ambient condition. Thereafter, the UV light irradiation, a post-exposure-bake (PEB) is carried out at 100 degrees Celsius for 60 seconds. The coating film is developed with NMD-3 (tetra-methyl ammonium hydroxide 2.38%, Tokyo Ohka Kogyo) for 60 seconds at 25 degrees Celsius and rinsed with deionized water for 10 seconds. The thickness of the coating film measured using a film thickness measurement tool is approximately 150 nm.

Sensitivity (Eₒ sensitivities) is evaluated by measuring the total doses to form a pattern constituted by 2-micrometer lines, where the thickness of the coating film is not zero, and 2-micrometer spaces, where the thickness of the coating film is zero.

Even if the UV exposure is carried out without a mask, 2-micrometer spaces are formed in the parts of the coating film that have been exposed to the EB and the LED. This indicates that a product functioning as a photosensitizer for the UV light is generated in the parts exposed to the EB exposure and the LED light exposure. On the other hand, 2-micrometer spaces are not formed by UV exposure without LED light exposures following EB exposure within a time frame in which the formation of the 2-micrometer spaces by the exposure of the coating film to the EB and the LED is completed.

The results indicate that the reduction of sulfonium cations of the PAGs and the PAG moiety with excitations of the radicals formed from corresponding reagents and moieties by LED light exposure is relatively effective, while the efficiency of reduction of the sulfonium cations without excitations of the ketyl radical is low. In other words, the excitation of ketyl radical by a visible light exposure is considered to enhance the interaction with the PAG. In other words, the excitation of such ketyl radical is considered to enhance its reducing character.

Table 2 shows the total doses corresponding to E₀ sensitivities measured for the Evaluation Samples. A light, the wavelength of which is 480 nm and outputted by optical parametric oscillation (OPO) and i-line (365 nm) are used as the visible light and the UV light, respectively.

TABLE 2
The doses for E₀ exposures to an EB, Visible Light
and UV exposure for the Evaluation Samples

| | | Total doses for E₀ | | |
|---|---|---|---|---|
| | Evaluation | EB dose | Visible light dose | UV dose |
| Run | Sample | [μC/cm²] | [mJ/cm²] | [mJ/cm²] |
| 1 | 1 | 30 | 0 | 0 |
| 2 | 2 | 30 | 0 | 0 |
| 3 | | 27 | 1520 | 0 |
| 4 | | 27 | 1520 | 3350 |
| 5 | 3 | 27 | 1520 | 0 |
| 6 | | 27 | 1520 | 3350 |
| 7 | 4 | 23 | 0 | 0 |
| 8 | | 19 | 1520 | 0 |
| 9 | | 19 | 1520 | 3350 |
| 10 | 5 | 23 | 0 | 0 |
| 11 | | 19 | 1520 | 0 |
| 12 | | 16 | 0 | 520 |
| 13 | | 12 | 1520 | 520 |
| 14 | 6 | 16 | 0 | 520 |
| 15 | | 12 | 1520 | 520 |
| 16 | 7 | 25 | 0 | 0 |
| 17 | | 21 | 1520 | 0 |
| 18 | | 21 | 1520 | 520 |
| 19 | 8 | 26 | 0 | 0 |
| 20 | | 22 | 1520 | 0 |
| 21 | | 23 | 0 | 520 |
| 22 | | 18 | 1520 | 520 |
| 23 | 9 | 22 | 0 | 520 |
| 24 | | 18 | 1520 | 520 |
| 25 | 10 | 25 | 0 | 0 |
| 26 | | 20 | 1520 | 0 |
| 27 | | 20 | 0 | 520 |
| 28 | | 14 | 1520 | 520 |
| 29 | 11 | 25 | 0 | 0 |
| 30 | | 20 | 1520 | 0 |
| 31 | | 22 | 0 | 520 |
| 32 | | 15 | 1520 | 520 |

The results of the Samples 2-11 in Table 2 indicate that the irradiations with the visible light improves sensitivity of the EB lithography by exciting the corresponding ketyl radicals generated by the visible light. The ketyl radicals are considered to become reducing species by excitation for PAGs.

The ketyl radical generated from Reagent 2 contained in Evaluation Sample 5 can donate its electron to DPI-PFBS even without excitation of the ketyl radical and is easily converted to a corresponding benzophenone. Therefore, the doses of EB can be reduced by performing a UV irradiation of the corresponding benzophenone even if no irradiation of the ketyl radical with the visible light is carried out. In other words, the iodonium PAG is reduced by the ketyl radical in the ground state because the iodonium PAG has enough electron-accepting ability.

In addition, sensitivities of Evaluation Samples 5, 6, 8 and 9-11 are improved by the UV exposure after the EB and the visible light exposure because DPI-PFBS and PBpS-PFBS are reduced by the excitation of ketone generated precursor in situ by the EB and the visible light exposure.

Ketyl radicals generated from Reagents 1 and 2 by having alpha hydrogen atoms of the hydroxyl groups abstracted are reducing characters for sulfonium and iodonium-type PAG by generated excited state by the visible light exposure because ketyl radical has an absorption band in the visible light region. In addition, ketones that are generated by oxidation of corresponding ketyl radicals exhibit longer absorption bands than the corresponding alcohols.

Reagents 1 and 2 can be used as acid generation enhancers (AGEs), which enable enhancing generation of acid from PAGs even if an inefficient process, such as generation of acid through an EUV exposure or an EB exposure, is employed. In other words, use of such reagents relating to an aspect of this disclosure enable performing multi-step lithographic exposure that can be used for a variety of devices such as a semiconductor device and an electro-optical device. Typically, after an EUV light or an EB is used for a first lithographic exposure, a light, the wavelength of which is longer than the EUV light is used for a second lithographic exposure.

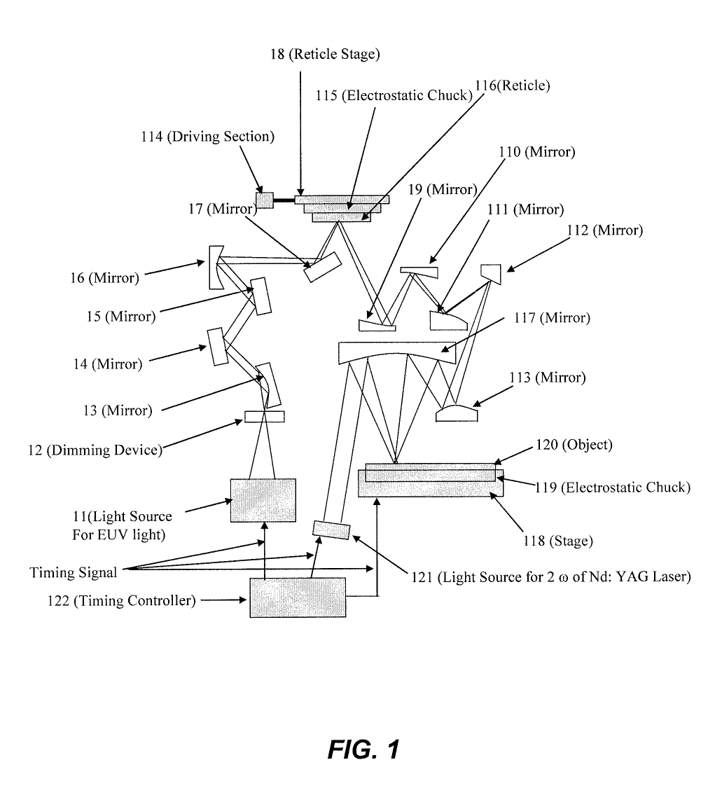

FIG. 1 shows a manufacturing apparatus equipped with an EUV light source and a laser light source relating to an aspect of this disclosure. The manufacturing apparatus has at least two light sources. The two light sources are Light Source 11, outputting an EUV light, and Light Source 121, outputting 2 omega (532 nm) of Nd:YAG Laser. In other words, Light Source 121 outputs a pulsed visible light. Timing of outputs of the EUV light from Light Source 11 and a 2-omega light of Nd:YAG Laser 121 and drive of Stage 118 are controlled by Timing Controller 122. Timing Controller 122 can also adjust a delay time between output of the EUV light and 2-omega light of Nd:YAG Laser. Adjustment of the delay time from an exposure of Object 120 to be processed placed on Stage 118 to the EUV light to an exposure of Object 120 to the 2 omega light of Nd:YAG Laser by using Timing Controller 122 enables exciting even a reactive intermediate, such as radical, ion, and chemical species containing an atom with unusual valence (e.g., carbene, silylene, etc.) having a lifetime generated from a reagent by the exposure to the EUV light contained in Object 120 within the lifetime by the 2-omega light of Nd:YAG Laser. In other words, the 2-omega light of Nd:YAG Laser is used for transient excitation of Object 120.

According to such reactive intermediate or chemical species desired to be excited, light sources can be selected instead of the 2-omega light of Nd:YAG Laser. 3-omega light of Nd:YAG Laser, 4-omega light of Nd:YAG Laser, excimer laser lights, and a Ti : Sapphire laser light (including its optical harmonic) are typical examples for the light sources. Use of optical parametric oscillation (OPO) or dye laser enables widening the wavelength region of a light that is used for exposure of Object 120 or excitation of reactive intermediates.

The EUV light outputted from light source 11 reaches object 120 through a plurality of mirrors 13-17, 19, 110-113 and 117. The mirrors are typically constituted by molybdenum-silicon multi-layer. The EUV light reflected by mirror 17 is reflected by mirror 19 after reflection by reticle 116 attached to reticle stage 118 through electrostatic chuck 115. The position of reticle 116 is controlled or driven by reticle stage 18.

Mirror 117 reflects both the EUV light and 2-omega light of Nd:YAG Laser. In other words, a part of the optical path through which the EUV light reaches object 120 can be shared with the optical path through which the 2-omega light of Nd:YAG Laser reaches object 120. Alternatively, at least one among the optical components constituting the manufacturing apparatus can be shared for the EUV exposure and the transient excitation.

It is preferred that the manufacturing apparatus is configured such that an area of a first portion of object 120 exposed to the EUV light is smaller than an area of a second portion of object exposed to the 2-omega light of Nd:YAG Laser . In other words, it is preferable that an exposed area by transient excitation or excitation with the visible light is larger than an exposed area by the EUV exposure. This enables reliably exciting a reactive intermediate generated in situ on or in object 120.

If a light for exciting such reactive intermediate generated in situ through the EUV exposure of object 120 or a chemical species generated through the EUV exposure of object 120 desired to be excited does not affect object 120 or a composition such as photoresist contained in object 120, a period in which the EUV exposure of object 120 is carried out can overlap temporally a period in which the exposure of object 120 with the light for exciting such intermediate or chemical species is carried out.

A product generated through the excitation of such intermediate or chemical species can be excited by using the manufacturing apparatus. According to the generated product, a light source for excitation of such product is selected arbitrarily. The 2-omega light of Nd:YAG Laser can be used for excitation of such product. If such generated product has at least two aromatic rings interacting each other, like ketone having two aryl groups or olefin having at least two aryl groups, it is preferred that the 3-omega light of Nd:YAG Laser be used for a reaction in which such product acts as a photosensitizer after the exposure of object 120 to the 2-omega light of Nd:YAG Laser. In that case, the irradiation of such generated product can be carried out using such manufacturing apparatus or outside of the manufacturing apparatus.

The excitation of the generated product or the photosensitizer can be carried out using the manufacturing apparatus. For example, in the case that Nd:YAG laser or Ti:Sapphire laser is a primary light source, use of wavelength conversion by harmonic generation or OPO of such primary light source enables such multiple use without changing apparatus.

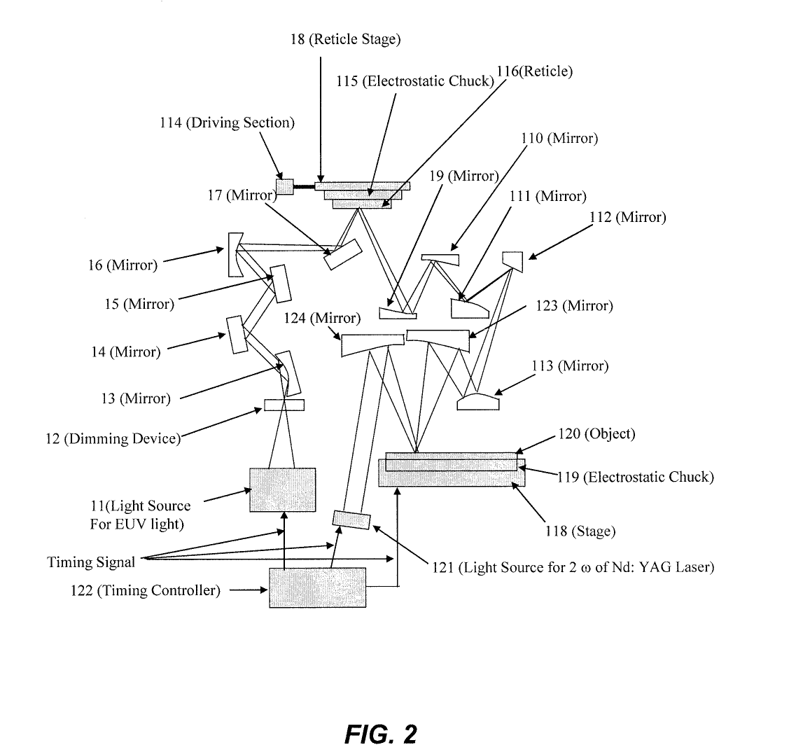

As shown in FIG. 2, the manufacturing apparatus may have mirror 123 for reflecting the EUV light and mirror 124 for reflecting the 2-omega light of Nd:YAG Laser independently. In other words, the optical path through which the EUV light reaches object 120 is not shared with the optical path through which the 2-omega light of Nd:YAG Laser reaches object 120 in the manufacturing apparatus shown in FIG. 2. Alternatively, no optical component among optical components constituting the manufacturing apparatus is shared for the EUV exposure and the transient excitation.

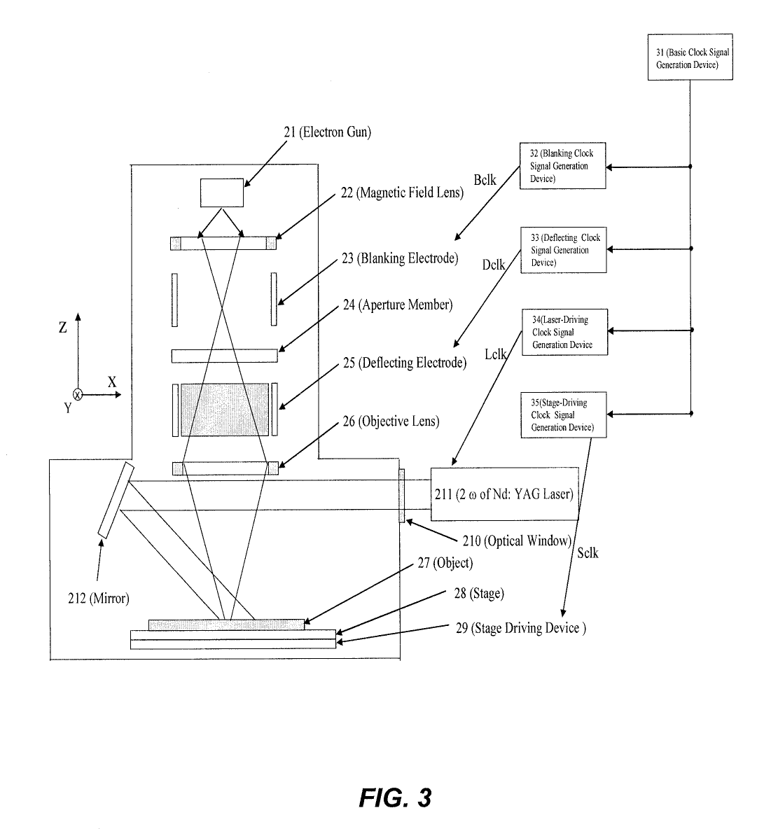

FIG. 3 shows a manufacturing apparatus equipped with an electron beam (EB) source and a laser light source relating to an aspect of this disclosure. The manufacturing apparatus having blanking electrode 23 and deflecting electrode 25. Blanking electrode 23 displaces the electron beam passing through magnetic field lens 22 toward the X-axis while the deflecting electrode displaces the electron beam passing through aperture member 24 disposed between blanking electrode 23 and deflecting electrode 25 toward the X-axis or the Y-axis.

The electron beam outputted from electron gun 21 and passing through magnetic field lens 22, aperture member 24 and objective lens 26 is focused on object 27 by objective lens 26.

2-omega of Nd:YAG Laser 211 enters inside of the manufacturing apparatus through optical window 210 and is reflected by mirror 212. The manufacturing apparatus is configured such that object 27 to be processed is exposed to the reflected light by mirror 212.

Basic clock signal generation device 31 controls blanking clock signal device 32, deflecting clock signal generation device 33, laser-driving clock signal generation device 34 and stage-driving clock signal generation device 35. Blanking clock signal device 31 and deflecting clock signal generation device 33 output Belk, which controls timing of blanking of the electron beam by using blanking electrode 23, and Dclk, which controls timing of deflection by using deflecting electrode 25, respectively. Laser-driving clock signal generation device 34 and stage-driving clock signal generation device 35 output Lclk, which controls timing of outputting of 2-omega of Nd:YAG Laser 211, and Sclk, which controls timing of driving stage 28 by using stage driving device 29, respectively.

It is preferred that the manufacturing apparatus is configured such that an area of a first portion of object 27 exposed to the EB is smaller than an area of a second portion of object exposed to the 2-omega light of Nd:YAG Laser. In other words, it is preferable that an exposed area by transient excitation or excitation with the visible light is larger than an exposed area by the EB exposure. This enables reliably exciting a reactive intermediate generated in situ on or in object 27.

If a light for exciting such reactive intermediate generated in situ through the EB exposure of object 27 or a chemical species generated through the EB exposure of object 27 desired to be excited does not affect object 120 or a composition such as photoresist contained in object 120, a period in which the EB exposure of object 27 is carried out can overlap temporally a period in which the exposure of object 27 with the light for exciting such intermediate or chemical species is carried out.

A product generated through the excitation of such intermediate or chemical species can be excited by using the manufacturing apparatus. According to the generated product, a light source for excitation of such product is selected arbitrarily. The 2-omega light of Nd:YAG Laser can be used for excitation of such product. If such generated product has at least two aromatic rings interacting each other like ketone having two aryl groups or olefin having at least two aryl groups, it is preferred that the 3-omega light of Nd:YAG Laser is used for a reaction in which such product acts as a photosensitizer after the exposure of object 27 to the 2-omega light of Nd:YAG Laser. In that case, the irradiation of such generated product can be carried out by using such manufacturing apparatus or outside of the manufacturing apparatus.

The excitation of the generated product or the photosensitizer can be carried out using the manufacturing apparatus. For example, in the case where Nd:YAG laser or Ti : Sapphire laser is a primary light source, use of wavelength conversion by harmonic generation or OPO of such primary light source enables such multiple uses without changing apparatus.

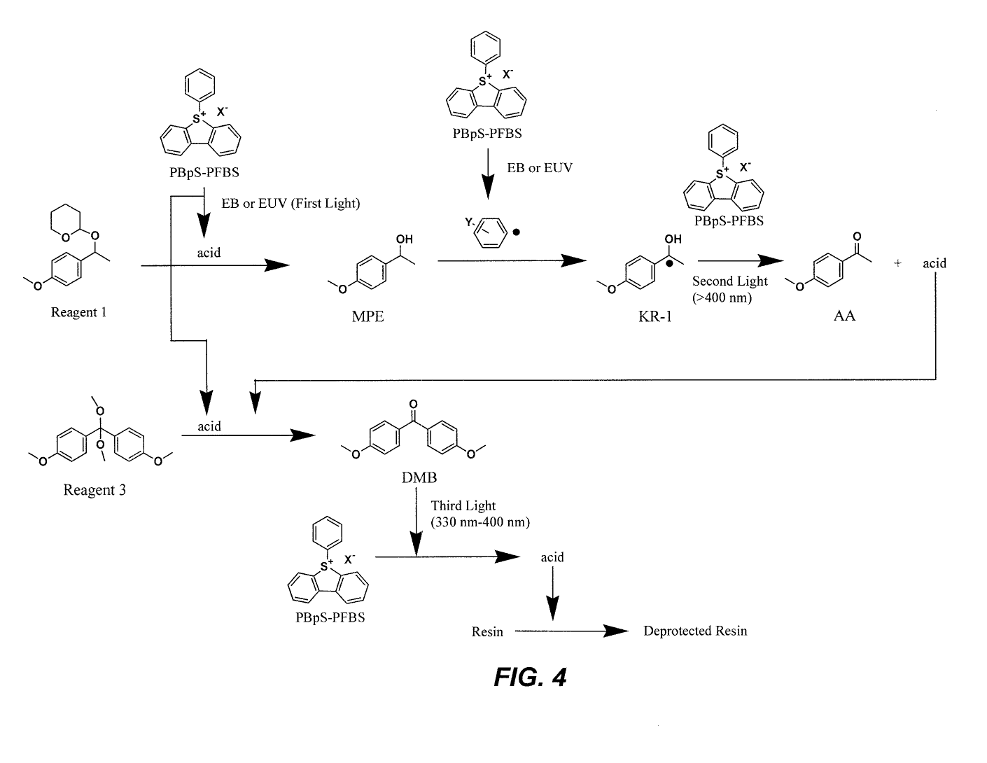

FIG. 4 shows a typical reaction scheme of a composition containing Reagent 1 and Reagent 3, which is related to an aspect of this disclosure and acts as a CAR. An exposure of PAG (PBpS-PFBS) to electron beam (EB) or extreme ultraviolet (EUV) light yields acid, which reacts with Reagent 1 to form a corresponding deprotected derivative or alcohol (MPE). MPE has a hydrogen atom bonded to carbon atom bonded to the hydroxyl group, which is easily abstracted by a radical such as phenyl radical. Abstraction of the hydrogen atom from the MPE forms a reactive intermediate such as ketyl radical (KR-1). KR-1 is converted into a corresponding ketone (AA) by reducing PBpS-PFBS through the excitation of KR-1 with a light, the wavelength of which is longer than 400 nm. The reduction of PBpS-PFBS yields acid.

Since Reagent I itself has hydrogen atom easily abstracted by a chemical intermediate such as radical, Reagent 1 can directly generate a corresponding ketyl radical not through an alcohol derivative like MPE. In contrast, since Reagent 3 has no hydrogen atom easily abstracted by a chemical intermediate, Reagent 3 does not yield a corresponding ketyl radical by having a hydrogen atom abstracted like Reagent 1.

Reagent 3 reacts with acid generated through the above process to form a corresponding ketone (DMB) in situ. DMB acts as a photosensitizer by absorbing a light such as a 3-omega of Nd:YAG Laser (355 nm) and an i-line light (365 nm). PBpS-PFBS receives an electron from the excited DMB to form acid.

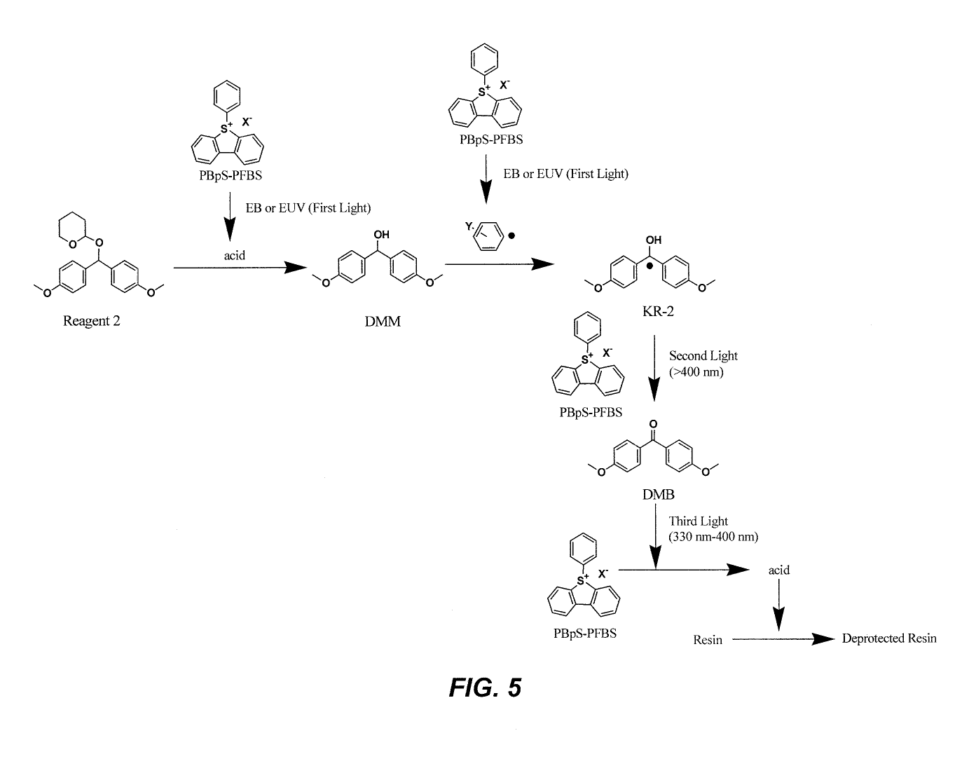

FIG. 5 shows a typical reaction scheme of a composition containing Reagent 2 relating to an aspect of this disclosure and acts as a CAR. An exposure of PAG (PBpS-PFBS) to electron beam (EB) or extreme ultraviolet (EUV) light yields acid, which reacts with Reagent 2 to form a corresponding deprotected derivative or alcohol (DMM). DMM has a hydrogen atom bonded to carbon atom bonded to the hydroxyl group, which is easily abstracted by a radical such as phenyl radical. Abstraction of the hydrogen atom from DMM forms a reactive intermediate such as ketyl radical (KR-2). KR-2 is converted into a corresponding ketone (DMB) by reducing PBpS-PFBS through the excitation of KR-2 with a light, the wavelength of which is longer than 400 nm. The reduction of PBpS-PFBS yields acid.

DMB acts as a photosensitizer by absorbing a light such as a 3-omega of Nd: YAG Laser (355 nm) and an i-line light (365 nm). PBpS-PFBS receives an electron from the excited DMB to form acid.

Since Reagent 2 itself has hydrogen atom easily abstracted by a chemical intermediate such as radical, Reagent 2 can directly generate a corresponding ketyl radical not through an alcohol derivative like DMM.

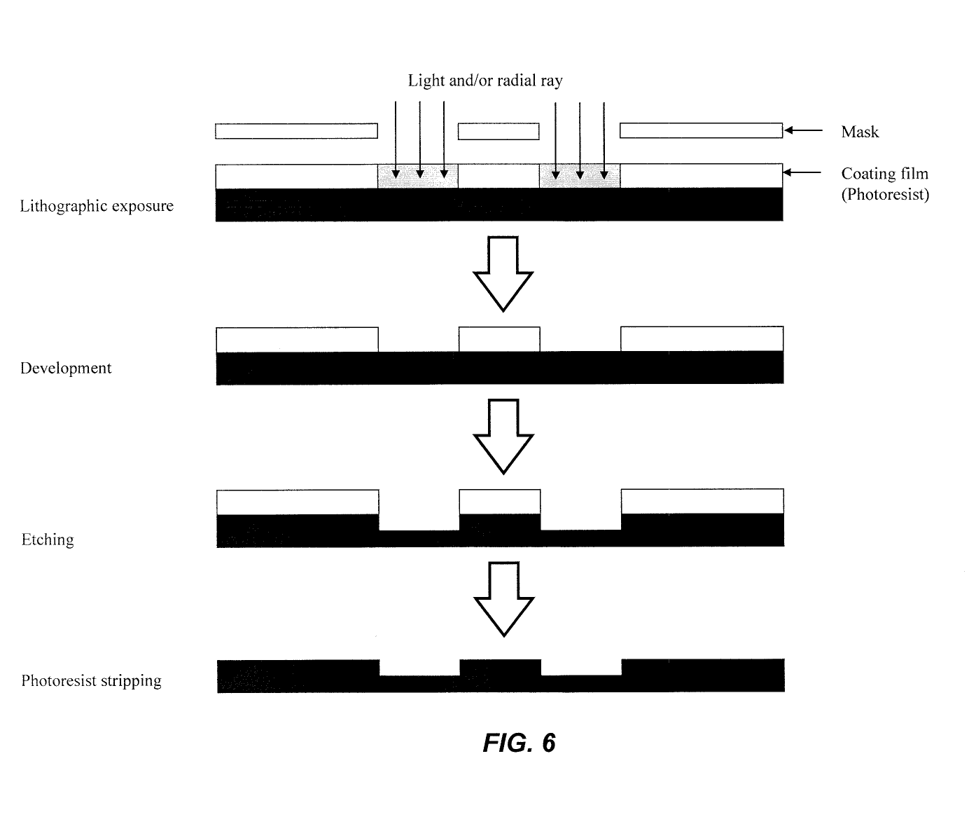

FIG. 6 shows fabrication processes of a device such as integrated circuit (IC) by using a CAR including Reagent 1 and the manufacturing apparatus shown in FIG. 1.

A silicon wafer is provided. The surface of the silicon wafer is oxidized by heating the silicon wafer in the presence of oxygen gas.

A solution of the CAR containing Reagent 2 is applied to the surface of an Si wafer by spin-coating to form a coating film. The coating film is prebaked.

Then, an irradiation of the coating film with an EUV light through a mask and an irradiation of a part including an irradiated portion with the EUV light of the coating film with a 2-omega of Nd:YAG Laser is carried out with 20-30 microseconds of a delay from the EUV irradiation. In other words, a transient excitation of the coating film is carried out by using the 2-omega of Nd:YAG Laser.

After the irradiation of the coating film with the EUV light and the transient excitation are carried out, an irradiation of the whole surface of coating film with a 3-omega of Nd:YAG Laser is carried out without mask. The 3-omega of Nd:YAG Laser can be outputted from the Nd:YAG Laser as a primary light source that has been used for outputting the 2-omega for the transient excitation.

Development of the coating film that has been irradiated with the EUV light, the 2-omega of Nd:YAG Laser and the 3-omega of Nd:YAG Laser is performed after the prebake.

The coating film and the silicon wafer are exposed to plasma. After that, the remaining film is removed.

An electronic device such as integrated circuit is fabricated utilizing the processes shown in FIG. 6. The deterioration of the device due to the irradiation with a light is suppressed compared to existing photoresists, since times for irradiation of the coating film is shortened.

1.-21. (canceled)

22. A composition used in the method of claim 42, the composition comprising:
a first reagent capable of generating a first chemical species in at least one of the composition, a solution containing the composition, and a film formed from the composition; and
a precursor that is capable of generating a second chemical species through an interaction with the first chemical species.

23. The composition of claim 22, wherein the first reagent is capable of generating the first chemical species through a first exposure of at least one of the composition, the solution, and the film to at least one of a first electromagnetic ray having a first wavelength and a first particle ray.

24. The composition of claim 22, wherein the precursor is capable of generating the second chemical species through a second exposure of at least one of the composition, the solution, and the film to at least one of a second electromagnetic ray having a second wavelength and a second particle ray.

25. The composition of claim 22, wherein:
the first chemical species is capable of generating a first product; and
the first product is capable of acting as a photosensitizer.

26. The composition of claim 22, wherein:
the first chemical species is capable of generating a first product; and
the precursor is capable of generating the second chemical species through a third exposure of at least one of the composition, the solution, and the film by at least one of a third electromagnetic ray having a third wavelength and a third particle ray.

27. The composition of claim 23, wherein the first electromagnetic ray and the first particle ray is an extreme ultraviolet light.

28. The composition of claim 26, wherein:
the third exposure is carried out using the third electromagnetic ray; and
the third wavelength is longer than 250 nm.

29. The composition of claim 24, wherein the second wavelength is longer than the third wavelength.

30.-41. (canceled)

42. A method of manufacturing a device, the method comprising: placing a composition on a member such that a film including the composition is disposed on the member;
first exposing the film to at least one of an electron beam and a first light, the wavelength of which is shorter than 50 nm;
second exposing the film to a second light, the wavelength of which is different than the first wavelength; and
third exposing the film to at least one of a third electromagnetic ray having a third wavelength and a third particle ray,
wherein
the second wavelength is longer than the third wavelength;
the third wavelength is longer than the first wavelength; and
the composition includes a first reagent able to generate a first chemical species and a precursor that generates a second chemical species.

43.-44. (canceled)

45. The method of claim 42, wherein a first period in which the first exposure is carried out does not overlap temporally a second period in which the second exposing exposure is carried out.

46. The method of claim 42, wherein:
the first chemical species is generated by the first exposure; and
the first chemical species is a ketyl radical.

47. The method of claim 42, wherein:
a first product is generated from the first chemical species; and
the first product is a ketone compound.

48. (canceled)

49. The method of claim 42, wherein the precursor generates a second chemical species by the third exposure.

50. The method of claim 42, wherein the first product enhances the generation of the second chemical species from the precursor by absorbing the third electromagnetic ray.

51. The method of claim 42,
wherein:
the first chemical species has a lifetime in the film; and
the first chemical species is excited within the lifetime of the first chemical species by the second exposure.

52. The method of claim 51, wherein:
the first chemical species is generated by the first exposure; and
the exciting of the first chemical species is carried out by the second exposure.

53. The method of claim 42, wherein the second wavelength is longer than 400 nm.

54. The method of claim 53, wherein the third wavelength is longer than 250 nm.

55. The method of claim 42, wherein the first reagent is an alcohol compound or an alcohol derivative with a hydroxyl group protected, as an acid generation enhancer.

56. The composition of claim 22, wherein the first reagent is an alcohol compound or an alcohol derivative with a hydroxyl group protected, as an acid generation enhancer.

57. The method of claim 42, wherein the first reagent is an alcohol derivative with a protected hydroxyl group.

58. The composition of claim 22, wherein the first reagent is an alcohol derivative with a protected hydroxyl group.

59. The composition of claim 23, wherein the first particle ray is an electron beam.
